(19) United States
(12) Patent Application Publication
(10) Pub. No.: US 2026/0095017 A1
(43) Pub. Date: Apr. 2, 2026

(54) PACKAGE HOUSING, LIDAR MODULE, AND AUTONOMOUS VEHICLE

(71) Applicant: HON HAI PRECISION INDUSTRY CO., LTD., New Taipei (TW)

(72) Inventors: HSIU-WEI KUO, New Taipei (TW); YU-TING LIAO, New Taipei (TW)

(21) Appl. No.: 19/294,718

(22) Filed: Aug. 8, 2025

(30) Foreign Application Priority Data
Sep. 30, 2024 (CN) 202411387122.0

(51) Int. Cl. H01S 5/02253; G01S 7/481; H01S 5/02257

(52) U.S. Cl. CPC H01S 5/02253; G01S 7/4813; H01S 5/02257

(57) ABSTRACT

Embodiments of the present disclosure relate to a package housing, a LiDAR module, and an autonomous vehicle. The package housing includes a tube shell, a first functional layer, a second functional layer, a first electrical pin, a second electrical pin and a temperature control layer. The tube shell includes an inner cavity with a first light-transmitting hole, a second light-transmitting hole, a first through hole and a second through hole. The first functional layer fills the first light-transmitting hole. The second functional layer fills the second light-transmitting hole. The first electrical pin fills the first through hole. The second electrical pin fills the second through hole. The temperature control layer is accommodated in the inner cavity.

### FIELD

The subject matter herein generally relates to light laser detection and ranging (LiDAR), specifically to a package housing, a LiDAR module, and an autonomous vehicle.

### BACKGROUND

The existing LiDAR module directly fixes multiple exposed components (such as a light-emitting module and a light-receiving module) and components of other functional modules on a circuit board, and a package housing is encapsulated close to the circuit board. Therefore, the air tightness of the LiDAR module is low and is greatly affected by environmental moisture, so that the durability of each component is not high. In addition, the existing LiDAR module further includes a filter encapsulated on the outer surface of the package housing, and the filter is usually formed by coating on transparent or colored glass, and the coating requires high precision and relatively large pieces. Specifically, the larger the size of the filter, the less conducive it is to improve the uniformity of the coating, and the larger the size of the filter, the higher the cost of glass and coating required to prepare the filter. When the chip components inside the LiDAR module are damaged, because there are other sensors or processor modules on the circuit board, the LiDAR module cannot be directly repaired, and the entire circuit board needs to be replaced, resulting in unnecessary waste of some modules and excessive maintenance costs.

Therefore, there is room for improvement in the art.

### BRIEF DESCRIPTION OF THE DRAWINGS

Implementations of the present disclosure will now be described, by way of embodiment, with reference to the attached figures.

FIG. 1 is a schematic structural diagram of a LiDAR module according to an embodiment of the present disclosure.

FIG. 2 is a schematic structural diagram of an optical phased array chip of the LiDAR module in FIG. 1.

FIG. 3 is a schematic structural diagram of a LiDAR module according to another embodiment of the present disclosure.

FIG. 4 is a schematic structural diagram of an optical phased array chip of the LiDAR module in FIG. 3.

FIG. 5 is a schematic structural diagram of an autonomous vehicle according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”.

Embodiments of the present disclosure provide a package housing and a LiDAR module using the package housing.

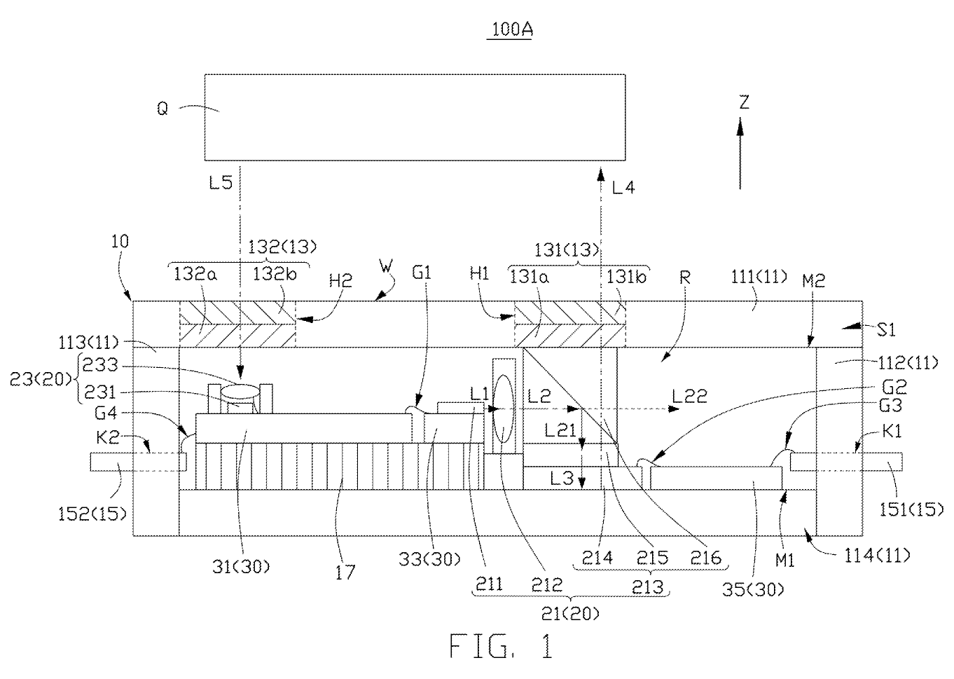

As shown in FIG. 1, a LiDAR module 100A of the first embodiment includes a package housing 10 and a laser transceiver module 20. The laser transceiver module 20 is accommodated in the package housing 10. The package housing 10 is used to hermetically package the laser transceiver module 20.

The package housing 10 includes a tube shell 11, a functional layer 13, an electrical pin 15 and a temperature control layer 17.

The tube shell 11 is a hollow shell and has an inner cavity R.

The tube shell 11 includes an upper cover 111, a base 114 opposite to the upper cover 111, and a plurality of side walls connecting the upper cover 111 and the base 114. The plurality of side walls includes a second side wall 112 and a third side wall 113 opposite the second side wall 112. The upper cover 111, the base 114, and the plurality of side walls jointly enclose the inner cavity R.

In some embodiments, the tube shell 11 is roughly a hollow cuboid, the number of the side walls is four and the four side walls enclose a rectangular frame.

The base 114 has a first cavity surface M1 facing the inner cavity R. The temperature control layer 17 is in the inner cavity R and is on the first cavity surface M1 of the base 114. The temperature control layer is used to cool the laser transceiver module 20.

The upper cover 111 has a second cavity surface M2 and an outer wall surface W opposite the second cavity surface M2. The outer wall surface W is farther away from the inner cavity R than the second cavity surface M2.

. A first light-transmitting hole H1 and a second light-transmitting hole H2 are formed at intervals in the upper cover 111 and penetrate the upper cover 111. The functional layer 13 includes a first functional layer 131 that can transmit light and a second functional layer 132 that can transmit light.

Specifically, the first functional layer 131 is embedded in the upper cover 111 and fills the first light-transmitting hole H1. The first functional layer 131 includes a first collimating lens 131a and a first filter 131b. The first collimating lens 131a is closer to the inner cavity R of the tube shell 11 than the first filter 131b. The first filter 131b is closer to the outer wall surface W of the upper cover 111 than the first collimating lens 131a.

The second functional layer 132 is embedded in the upper cover 111 and fills the second light-transmitting hole H2. The second functional layer 132 includes a first light-collecting mirror 132a and a second filter 132b. The first light-collecting mirror 132a is closer to the inner cavity R of the tube shell 11 than the second filter 132b, and the second filter 132b is closer to the outer wall surface W of the upper cover 111 than the first light-collecting mirror 132a.

At least one first through hole K1 penetrates the second side wall 112. At least one second through hole K2 penetrates the third side wall 113. The first through hole K1 and the second through hole K2 are opposite to each other.

The electrical pin 15 includes a first electrical pin 151 and a second electrical pin 152. The first electrical pin 151 passes through the second side wall 112 and fills the first through hole K1, and the second electrical pin 152 passes through the third side wall 113 and fills the second through hole K2.

Since the first through hole K1 and the second through hole K2 are opposite to each other, the first electrical pin 151 and the second electrical pin 152 are also opposite to each other.

The electrical pin 15 can be made of metal or other conductive material.

The package housing 10 provided in the first embodiment of the present disclosure uses the tube shell 11 with a sealed inner cavity R for airtight packaging, so as to reduce the influence of ambient moisture on internal modules in the package housing 10, thereby improving the reliability of the overall product and reducing maintenance costs. In addition, the package housing 10 is provided with the first functional layer 131 that can transmit light and the second functional layer 132 that can transmit light on the tube shell 11, thus enriching the functions of the package housing 10 in optical applications. Further, the package housing 10 accommodates the temperature control layer 17 in the inner cavity R for cooling, prevents the temperature of the package housing 10 from overheating, and further improves the reliability of the overall product.

The laser transceiver module 20 is accommodated in the inner cavity R of the package housing 10. The laser transceiver module 20 includes a and a light-receiving module 23. The light-emitting module 21 is used to emit reference light L4 to a target Q to be measured, and the light-receiving module 23 is used to receive detection light L5 reflected by the target Q according to the reference light L4 and obtain distance information of the target Q according to the detection light L5.

When the laser transceiver module 20 is in a working mode, the first functional layer 131 is on the optical path of the reference light L4. The reference light L4 emitted by the light-emitting module 21 sequentially passes through the first collimating lens 131a and the first filter 131b before being emitted to the target Q. The second functional layer 132 is on the optical path of the detection light L5, and the detection light L5 sequentially passes through the second filter 132b and the first light-receiving mirror 132a before being received by the light-receiving module 23. Therefore, the first functional layer 131 is opposite to the light-emitting module 21, and the second functional layer 132 is opposite to the light-receiving module 23.

In one embodiment, the first filter 131b is a low-pass filter (LPF), and the second filter 132b is a narrow-band filter (NBPF). Both the LPF and the NBPF are used to select the wavelength range of the incident light beam, which is equivalent to passing the light beam within the target wavelength band and blocking the light beam within the non-target wavelength band.

Specifically, the LPF can filter the light beam with wavelength below 1000 nanometers and has the advantage of low cost. The filtering accuracy of the NBPF is higher than that of the LPF, and the NBPF can filter all light beams except the narrow band around 1550 nanometers.

In one embodiment, the working wavelength bands of the reference light L4 and the detection light L5 are both 1550 nanometers, but the optical sensor 231 can sense light beams ranging from 900 to1700 nanometers. Based on this, if the second filter 132b is not used, the light beam received by the light-receiving module 23 cannot be filtered to purify the detection light L5. As a result, the accuracy of the optical sensor 231 will be reduced due to the interference of ambient light (such as, sunlight) and other non-target detection light at 905 to 940 nanometers used by other LiDAR modules. Meanwhile, if the first filter 131b is not used, the ambient light or the non-target detection light will flow back into the light-emitting module 21, and even be incident on the laser source, causing the temperature of the LiDAR module to be too high, resulting in the wavelength of a source light L1 being lower than 1550 nanometers, and indirectly affecting the accuracy of the optical sensor 231.

In other embodiments, the first filter 131b and the second filter 132b can be the NBPF.

The light-emitting module 21 includes a laser source 211, a second collimating lens 212 and a scanning module 213.

The laser source 211 is used to emit the source light L1. The laser source 211 includes at least one light emitting array composed of lasers, such as an edge emitting laser (EEL) or a fiber laser (FL), which meet the range performance requirements. Accordingly, the source light L1 includes at least the light emitted by at least one laser in the light-emitting array. In the figure, only the optical path transformation of a beam of light emitted by one laser is shown for clarity of the optical path.

The second collimating lens 212 is located on the optical path of the source light L1 and is used to collimate the source light L1 into a parallel light L2. Due to the strong divergence of the light emitted by the laser, it is necessary to collimate the laser. Additionally, due to the low power of a single laser, it is also necessary to collimate multiple lasers before combining them into a beam.

In one embodiment, the second collimating lens 212 is a fast-slow axis integrated collimating lens. In the optical field, the direction of the light vector with a slow propagation speed in the wave plate is called the slow axis, and the direction of the light vector with a fast propagation speed in the wave plate is called the fast axis. The fast-slow axis integrated collimating lens can simultaneously collimate the fast axis and slow axis of the light source L1, thereby simultaneously reducing the divergence of the light beams on the fast axis and the slow axis and reducing the light spot, generating a symmetrical light beam, and presenting a nearly circular far-field profile.

The fast-slow axis integrated collimating lens only includes one lens, which further reduces the volume compared to the existing technology of a separate collimating lens formed by closely combining a fast axis collimating lens and a slow axis collimating lens.

In addition, unlike the effect of the separate collimating lens that first collimates the fast axis and then collimates the slow axis, the fast-slow axis integrated collimating lens collimates the light beam on both the fast and slow axes, which helps to improve the symmetry of the light beam and is equivalent to improving the uniformity of the light spot.

In addition, the first collimating lens 131a is also a fast-slow axis integrated collimating lens. The first collimating lens 131a is on the optical path of the reference light L4, which is used to collimate the fast axis and slow axis of the reference light L4 simultaneously, further reducing the light spot, ensuring the light-emitting effect of the light-emitting module 21, and eliminating the problem of too large light spot when the reference light L4 propagates to a long distance.

In one embodiment, the applicable distance of the reference light L4 is 200 meters.

The scanning module 213 is used to convert at least a portion of the parallel light L2 into the reference light L4. Specifically, the scanning module 213 includes an optical phased array chip 214, a quarter wave plate 215 and a polarization beam splitter 216, which are stacked from bottom to top in a vertical structure. That is, the projections of the optical phased array chip 214, the quarter-wave plate 215, and the polarization beam splitter 216 in the vertical direction (shown as the Z-axis direction in the figure) all have overlapping parts. The vertical structure can reduce the volume of the scanning module 213 and further shorten the response time of the scanning module 213.

The three optical components of the scanning module 213 can be fixed to each other by bonding with optical adhesive (not shown). The optical adhesive is a double-sided film made of a light-transmitting medium and matched with the optical components to be bonded, such as optical clear resin (OCR) and optical clear adhesive (OCA), both of which have the characteristics of high light transmittance.

The polarization beam splitter 216 is located on the optical path of the parallel light L2. The parallel light L2 includes a first laser L21 and a non-working light L22. The first laser L21 has a first polarization direction, and the non-working light L22 has a second polarization direction different from the first polarization direction.

Since the polarization beam splitter 216 can split the incident light into S-polarized light and P-polarized light and reflect the S-polarized light while transmitting the P-polarized light, the polarization beam splitter 216 is used to split the first laser L21 and the non-working light L22 of the parallel light L2, emit the first laser L21 and the non-working light L22 in different directions and guide the first laser L21 to the quarter wave plate 215.

In one embodiment, the first laser L21 is S-polarized light, and the non-working light L22 is P-polarized light.

In other embodiments, the first laser L21 can be P-polarized light, and the non-working light L22 can be S-polarized light. Since the non-working light L22 does not participate in the formation of the reference light L4, the non-working light L22 can be recycled. In order to distinguish the non-working light L22 from the first laser L21, the non-working light L22 is marked with a dashed line in the figure.

The quarter wave plate 215 is on the optical path of the first laser L21 and is used to transmit the first laser L21 from the polarization beam splitter 216 to emit the second laser L3. The second laser L3 has a third polarization direction different from the first polarization direction and the second polarization direction.

Specifically, when the first laser L21 is S-polarized light, the second laser L3 emitted after passing through the quarter-wave plate 215 is circularly polarized light.

The optical phased array chip 214 is located on the optical path of the second laser L3 and is used to receive the second laser L3 from the quarter-wave plate 215 to emit the reference light L4 to the target Q.

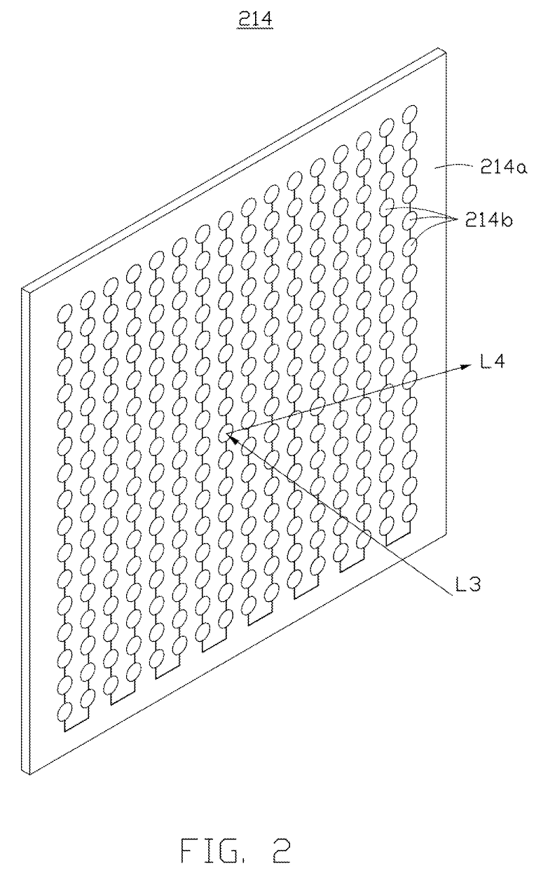

As shown in FIG. 1 and FIG. 2, the optical phased array chip 214 includes a grating surface 214a close to the quarter-wave plate 215, and a plurality of grating units 214b arranged in an array are formed on the grating surface 214a.

In other embodiments, the structure and arrangement of the grating unit 214b are not limited to those shown in FIG. 2.

In one embodiment, the optical phased array chip 214 is a reflective optical phased array chip, and the grating unit 214b is a reflective grating. After the second laser L3 is guided to the grating surface 214a, the second laser L3 is refracted at the grating unit 214b and is reflected at the same time to generate the reference light L4. Specifically, the second laser L3 is reflected and then interfered, that is, when overlapping in space, it is superimposed to form the reference light L4. More specifically, the light emitted by all grating units 214b is a reference light L4 emitted in a certain direction, and due to the light emitted by the grating unit 214b has different collection directions (i.e., different interference directions), the reference light L4 can be emitted in multiple directions.

For ease of understanding, arrows are used in the figure to show the incident second laser L3 and the emitted reference light L4.

The quarter-wave plate 215 and the polarization beam splitter 216 are also located on the optical path of the reference light L4. The emitted reference light L4 passes through the quarter-wave plate 215 and the polarization beam splitter 216 in sequence, and then reaches the target Q in a direction different from the emission direction of the first laser L21 and the non-working light L22. After passing through the quarter-wave plate 215, the reference light L4 changes from circularly polarized light to P-polarized light.

The light-receiving module 23 includes an optical sensor 231 and a second light-collecting lens 233. The optical sensor 231 is used to obtain the distance information of the target Q based on the detection light L5. The second light-collecting lens 233 is used to converge and guide the detection light L5 to the optical sensor 231, and the second light-collecting lens 233 surrounds the optical sensor 231.

Since the detection light L5 has been collected by the first light-collecting mirror 132a of the second functional layer 132, the second light-collecting lens 233 further collects the detection light L5 for a second time.

In one embodiment, the first light-collecting mirror 132a and the second light-collecting lens 233 can be selected to include lenses that satisfy the light collecting effect, such as aspherical lenses, Fresnel lenses or free-form surface lenses.

In addition, the optical sensor 231 can convert the received optical signal (i.e., detection light L5) into an electrical signal, which can be used in ranging algorithms such as time of flight (TOF), amplitude modulated continuous wave (AMCW), and frequency modulated continuous wave (FMCW) to calculate and obtain the position information of the target Q.

The LiDAR module 100A further includes a built-in circuit board module 30, which is accommodated in the inner cavity R of the package housing 10. The built-in circuit board module 30 is a small circuit board whose volume meets the requirements of accommodation space and conductivity.

The laser transceiver module 20 and the built-in circuit board module 30 are both on the first cavity surface M1 of the base 114.

The built-in circuit board module 30 includes a first circuit board 31, a light source driving board 33, and a chip driving board 35.

The first circuit board 31 and the light source driving board 33 are spaced apart and fixed on the surface of the temperature control layer 17 away from the base 114. A first wire G1 is connected between the first circuit board 31 and the light source driving board 33, so that the first circuit board 31 can supply power to the light source driving board 33.

The light-receiving module 23 is fixed on the surface of the first circuit board 31 away from the temperature control layer 17. The optical sensor 231 is on the temperature control layer 17, and the second light-collecting lens 233 is on the side of the optical sensor 231 away from the temperature control layer 17.

The laser source 211 is fixed on the surface of the light source driving board 33 away from the temperature control layer 17, and the light source driving board 33 is used to drive the laser source 211 to emit light.

The chip driving board 35, the second collimating lens 212 and the scanning module 213 are fixed at intervals on the same surface with the temperature control layer 17. The chip driving board 35 is electrically connected to the optical phased array chip 214 of the scanning module 213 through a second wire G2. The chip driving board 35 can output control voltages of different voltage values to change the physical optical properties of the grating unit 214b, thereby changing the emission direction of the light at the grating unit 214b.

For example, the control voltages are used to change the refractive index of the grating unit 214b. When the second laser L3 is refracted in all grating units 214b, the emission direction of the reference light L4 formed by reflection or transmission is affected by the refractive index and changes accordingly.

In one embodiment, the chip driving board 35 is an application-specific integrated circuit (ASIC) chip.

The chip driving board 35 and the first electrical pin 151 are electrically connected through a third wire G3. The first circuit board 31 and the second electrical pin 152 are electrically connected through a fourth wire G4.

The electrical pins 15 (such as, the first electrical pin 151 and the second electrical pin 152) are electrically connected to external power sources or welded to a large circuit board to power the first circuit board 31, the light source driving board 33 and the chip driving board 35, thereby supplying power to the laser transceiver module 20.

The electrical pins 15 can be sealed with multilayer ceramics or coaxial cables to meet the high-speed signal interconnection.

In one embodiment, the first wire G1, the second wire G2, the third wire G3 and the fourth wire G4 are gold wires, which have good conductivity.

In one embodiment, the temperature control layer 17 is a thermoelectric cooler (TEC), which can achieve the required cooling degree and accuracy of optical components. Specifically, the temperature control layer 17 prevents the temperature of the laser transceiver module 20 from being too high by actively cooling and controlling the temperature of the first circuit board 31 and the light source driving board 33 that are in direct contact, thereby maintaining the signal transmission efficiency and accuracy of the entire laser transceiver module 20. If the temperature is not controlled, the temperature of the laser transceiver module 20 will be too high, the efficiency of signal transmission will decrease, the wavelength of the laser will change, and the laser transceiver module 20 will not be able to operate normally.

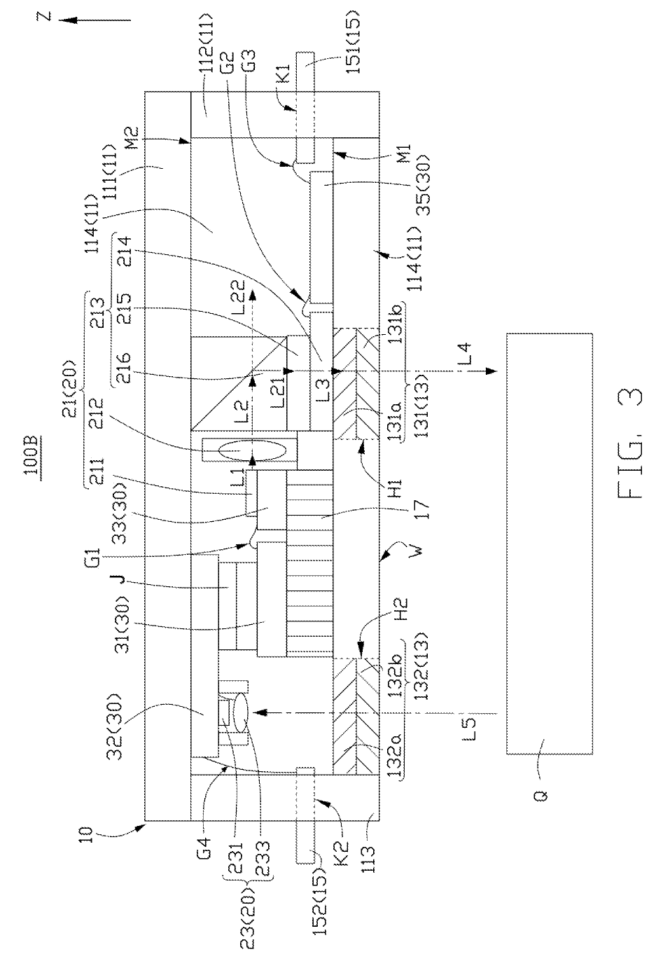

As shown in FIG. 3, in a LiDAR module 100B of a second embodiment, the first functional layer 131 and the second functional layer 132 are embedded in the base 114.

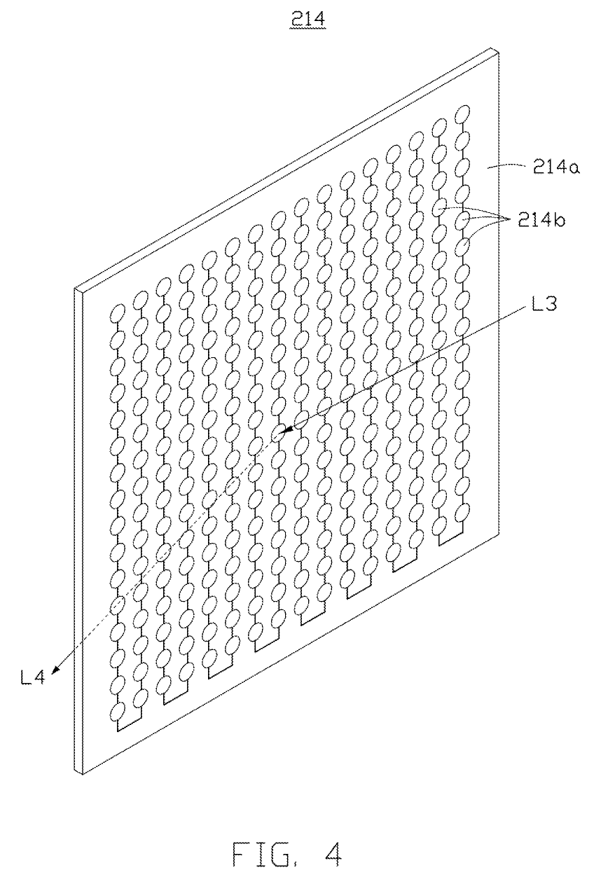

As shown in FIG. 3 and FIG. 4, the optical phased array chip 214 is a transmission optical phased array chip, and the grating unit 214b is a transmission grating. After the second laser L3 is guided to the grating surface 214a, the second laser L3 is refracted at the grating unit 214b and simultaneously transmitted to form the reference light L4.

Specifically, after the second laser L3 is transmitted, interference occurs. That is, after the second laser L3 is transmitted, it overlaps in space to form the reference light L4. After the optical phased array chip 214 emits the reference light L4, the reference light L4 directly passes through the first functional layer 131 and then emits to the target Q.

The laser transceiver module 20 and some components of the built-in circuit board module 30 are on the first cavity surface M1 of the base 114, and the other components of the built-in circuit board module 30 are on the second cavity surface M2 of the upper cover 111.

Specifically, the built-in circuit board module 30 further includes a second circuit board 32, which is located on the second cavity surface M2 of the upper cover 111 and faces the first circuit board 31. The first circuit board 31 and the second circuit board 32 are electrically connected and bonded by a conductive adhesive J.

In addition to the positional relationship described above, the light-receiving module 23 is on the surface of the second circuit board 32 facing the temperature control layer 17. The optical sensor 231 is on the surface of the temperature control layer 17, and the second light-collecting lens 233 is on the side of the optical sensor 231 close to the temperature control layer 17.

In addition to the above differences compared with the LiDAR modules 100A of the first embodiment, the LiDAR modules 100B of the second embodiment also has the same technical features as the first embodiment.

The LiDAR modules 100A and 100B accommodate the laser transceiver module 20 in the inner cavity R of the package housing 10 with high reliability, so as to reduce the maintenance cost of the LiDAR module and facilitate modularization. When a fault occurs, the independent LiDAR module can be directly replaced.

The first collimating lens 131a and the first filter 131b of the first functional layer 131 of the package housing 10 cooperate with the second collimating lens 212 of the light-emitting module 21 to filter, purify and collimate the reference light L4 twice, which is conducive to improving the detection distance and scanning accuracy.

In addition, the first light-collecting mirror 132a and the second filter 132b of the second functional layer 132 of the package housing 10 cooperate with the second light-collecting lens 233 of the light-collecting module 23 to filter, purify and collect the detection light L5 twice, which is equivalent to collecting light at a larger angle, thereby improving the detection angle.

The package housing has the characteristics of modularity, high reliability, and multifunctionality, which simplifies the assembly process of the LiDAR module, and is conducive to reducing the volume, improving the integration effect, achieving detection automation, convenient maintenance, and reducing maintenance costs.

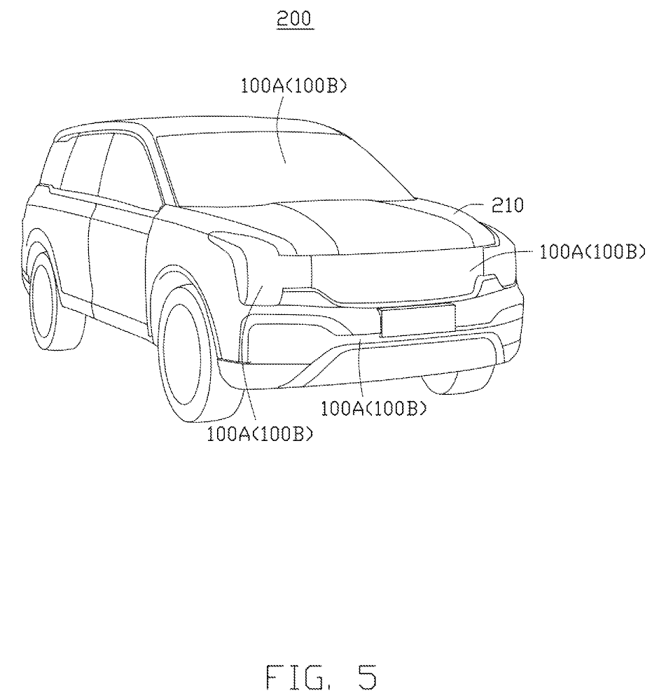

As shown in FIG. 5, an autonomous vehicle 200 includes the LiDAR module 100A (100B) and a vehicle body 210. The LiDAR module 100A (100B) is fixed on the vehicle body 210 and is used to detect whether there is a target Q to be measured on the travel path of the vehicle body 210. When there is a target Q to be measured, the LiDAR module 100A (100B) obtains the distance information of the target Q. For example, the LiDAR module 100A (100B) can be installed on the windshield, headlights, bumper and front grille of the vehicle body 210 to automatically identify and avoid obstacles while driving.

The autonomous vehicle 200 provided in the embodiment of the present disclosure fixes the LiDAR module 100A (100B) on the vehicle body 210 for scanning and ranging, fully utilizing the advantages of high reliability and low maintenance cost of the LiDAR module 100A (100B), which helps the autonomous vehicle 200 better avoid obstacles in front of the vehicle while driving.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A package housing comprises:
a tube shell comprising an inner cavity with a first light-transmitting hole, a second light-transmitting hole, a first through hole and a second through hole;
a first functional layer filling the first light-transmitting hole, the first functional layer comprising a first collimating lens and a first filter on a side of the first collimating lens away from the inner cavity;
a second functional layer filling the second light-transmitting hole, the second functional layer comprising a first light-collecting mirror and a second filter on a side of the first light-collecting mirror away from the inner cavity;
a first electrical pin filling the first through hole;
a second electrical pin filling the second through hole; and
a temperature control layer accommodated in the inner cavity.

2. The package housing according to claim 1, wherein the first collimating lens is a fast-slow axis integrated collimating lens.

3. The package housing according to claim 1, wherein the first filter is a low-pass filter, and the second filter is a narrow-band filter.

4. The package housing according to claim 1, wherein each of the first filter and the second filter is a narrow-band filter.

5. The package housing according to claim 1, wherein the tube shell comprises a base, an upper cover opposite to the base, a second side wall connecting the base and the upper cover, and a third side wall opposite to the second side wall and connecting the base and the upper cover; the first light-transmitting hole and the second light-transmitting hole are formed on the upper cover, or the first light-transmitting hole and the second light-transmitting hole are formed on the base; the first through hole is formed on the second side wall; and the second through hole is formed on the third side wall.

6. A light laser detection and ranging (LiDAR) module comprising:
a package housing comprising:
a tube shell comprising an inner cavity with a first light-transmitting hole, a second light-transmitting hole, a first through hole and a second through hole;
a first functional layer filling the first light-transmitting hole, the first functional layer comprising a first collimating lens and a first filter on a side of the first collimating lens away from the inner cavity;
a second functional layer filling the second light-transmitting hole, the second functional layer comprising a first light-collecting mirror and a second filter on a side of the first light-collecting mirror away from the inner cavity;
a first electrical pin filling the first through hole;
a second electrical pin filling the second through hole; and
a temperature control layer accommodated in the inner cavity; and
a laser transceiver module in the inner cavity and in direct contact with the temperature control layer, the temperature control layer being configured to cool the laser transceiver module, the laser transceiver module comprising:
a light-emitting module opposite to the first functional layer and electrically connected to the first electrical pin, the light-emitting module being configured to emit a reference light to a target to be measured; and
a light-receiving module opposite to the second functional layer and electrically connected to the second electrical pin, the light-emitting module being configured to receive a detection light reflected from the target and obtain position information of the target according to the reference light;
wherein the reference light sequentially passes through the first collimating lens and the first filter before being emitted to the target, and the detection light sequentially passes through the second filter and the first light-receiving mirror before being received by the light-receiving module.

7. The LiDAR module according to claim 6, wherein the first collimating lens is a fast-slow axis integrated collimating lens, and the second collimating lens is a fast and slow axis integrated collimating lens.

8. The LiDAR module according to claim 6, wherein the first filter is a low-pass filter, and the second filter is a narrow-band filter.

9. The LiDAR module according to claim 6, wherein each of the first filter and the second filter is a narrow-band filter.

10. The LiDAR module according to claim 6, wherein the tube shell comprises a base, an upper cover opposite to the base, a second side wall connecting the base and the upper cover, and a third side wall opposite to the second side wall and connecting the base and the upper cover; the first light-transmitting hole and the second light-transmitting hole are formed on the upper cover, or the first light-transmitting hole and the second light-transmitting hole are formed on the base; the first through hole is formed on the second side wall; and the second through hole is formed on the third side wall.

11. The LiDAR module according to claim 6, wherein the light-emitting module comprises a laser source, a second collimating lens and a scanning module, the laser source is configured to a source light, the second collimating lens is configured to collimate the source light into a parallel light, the scanning module is configured to convert at least a portion of the parallel light into the reference light; the light-receiving comprises an optical sensor and a second light-collecting lens, the optical sensor is configured to obtain distance information of the target, and the second light-collecting lens is configured to converge and guide the detection light to the optical sensor.

12. The LiDAR module according to claim 11, wherein the scanning module comprises:
a polarization beam splitter on an optical path of the parallel light and configured to split the parallel light into a first laser with a first polarization direction and a non-working light with a second polarization direction and emit the first laser and the non-working light in different directions, the second polarization direction being different from the first polarization direction;
a quarter wave plate on an optical path of the first laser and configured to receive the first laser and emit a second laser with a third polarization direction, the third polarization direction being different from the first polarization direction and the second polarization direction; and
an optical phased array chip on an optical path of the second laser and configured to receive the second laser and emit the reference light.

13. The LiDAR module according to claim 12, wherein the optical phased array chip is a reflective optical phased array chip or a transmissive optical phased array chip.

14. An autonomous vehicle comprising a vehicle body and a light laser detection and ranging (LiDAR) module on the vehicle body, the LiDAR module comprising:
a package housing comprising:
a tube shell comprising an inner cavity with a first light-transmitting hole, a second light-transmitting hole, a first through hole and a second through hole;
a first functional layer filling the first light-transmitting hole, the first functional layer comprising a first collimating lens and a first filter on a side of the first collimating lens away from the inner cavity;
a second functional layer filling the second light-transmitting hole, the second functional layer comprising a first light-collecting mirror and a second filter on a side of the first light-collecting mirror away from the inner cavity;
a first electrical pin filling the first through hole;
a second electrical pin filling the second through hole; and
a temperature control layer accommodated in the inner cavity; and
a laser transceiver module in the inner cavity and in direct contact with the temperature control layer, the temperature control layer being configured to cool the laser transceiver module, the laser transceiver module comprising:
a light-emitting module opposite to the first functional layer and electrically connected to the first electrical pin, the light-emitting module being configured to emit a reference light to a target to be measured; and
a light-receiving module opposite to the second functional layer and electrically connected to the second electrical pin, the light-emitting module being configured to receive a detection light reflected from the target and obtain position information of the target according to the reference light;
wherein the reference light sequentially passes through the first collimating lens and the first filter before being emitted to the target, and the detection light sequentially passes through the second filter and the first light-receiving mirror before being received by the light-receiving module.

15. The autonomous vehicle according to claim 14, wherein the first collimating lens is a fast-slow axis integrated collimating lens, and the second collimating lens is a fast and slow axis integrated collimating lens.

16. The autonomous vehicle according to claim 14, wherein the first filter is a low-pass filter, and the second filter is a narrow-band filter; or each of the first filter and the second filter is a narrow-band filter.

17. The autonomous vehicle according to claim 14, wherein the tube shell comprises a base, an upper cover opposite to the base, a second side wall connecting the base and the upper cover, and a third side wall opposite to the second side wall and connecting the base and the upper cover; the first light-transmitting hole and the second light-transmitting hole are formed on the upper cover, or the first light-transmitting hole and the second light-transmitting hole are formed on the base; the first through hole is formed on the second side wall; and the second through hole is formed on the third side wall.

18. The autonomous vehicle according to claim 14, wherein the light-emitting module comprises a laser source, a second collimating lens and a scanning module, the laser source is configured to a source light, the second collimating lens is configured to collimate the source light into a parallel light, the scanning module is configured to convert at least a portion of the parallel light into the reference light; the light-receiving comprises an optical sensor and a second light-collecting lens, the optical sensor is configured to obtain distance information of the target, and the second light-collecting lens is configured to converge and guide the detection light to the optical sensor.

19. The autonomous vehicle according to claim 18, wherein the scanning module comprises:
a polarization beam splitter on an optical path of the parallel light and configured to split the parallel light into a first laser with a first polarization direction and a non-working light with a second polarization direction and emit the first laser and the non-working light in different directions, the second polarization direction being different from the first polarization direction;
a quarter wave plate on an optical path of the first laser and configured to receive the first laser and emit a second laser with a third polarization direction, the third polarization direction being different from the first polarization direction and the second polarization direction; and
an optical phased array chip on an optical path of the second laser and configured to receive the second laser and emit the reference light.

20. The LiDAR module according to claim 19, wherein the optical phased array chip is a reflective optical phased array chip or a transmissive optical phased array chip.
